(19) United States
(12) Patent Application Publication
(10) Pub. No.: US 2021/0073645 A1
(43) Pub. Date: Mar. 11, 2021

(54) LEARNING APPARATUS AND METHOD, AND PROGRAM

(71) Applicant: SONY CORPORATION, TOKYO (JP)

(72) Inventor: YOSUKE KASHIWAGI, TOKYO (JP)

(21) Appl. No.: 16/959,540

(22) PCT Filed: Dec. 27, 2018
(86) PCT No.: PCT/JP2018/048005

§ 371 Date: Jul. 1, 2020

(30) Foreign Application Priority Data
Jan. 10, 2018 (JP) 2018-001904

(51) Int. Cl. G06N 3/08; G10L 15/16; G10L 25/30; G10L 19/00; H03M 7/30; G06F 7/58

(52) U.S. Cl. CPC G06N 3/084; G10L 15/16; G10L 25/30; H03M 7/3062; H03M 7/6011; H03M 7/6005; G06F 7/58; G10L 19/00

(57) ABSTRACT

The present technology relates to a learning apparatus and method, and a program which allow speech recognition with sufficient recognition accuracy and response speed. A learning apparatus includes a model learning unit that learns a model for recognition processing, on the basis of output of a decoder for the recognition processing constituting a conditional variational autoencoder when features extracted from learning data are input to the decoder, and the features. The present technology can be applied to learning apparatuses.

### TECHNICAL FIELD

The present technology relates to a learning apparatus and method, and a program, and more particularly, relates to a learning apparatus and method, and a program which allow speech recognition with sufficient recognition accuracy and response speed.

### BACKGROUND ART

In recent years, demand for speech recognition systems has been growing, and attention has been focusing on methods of learning acoustic models that play an important role in speech recognition systems.

For example, as techniques for learning acoustic models, a technique of utilizing speeches of users whose attributes are unknown as training data (see Patent Document 1, for example), a technique of learning an acoustic model of a target language using a plurality of acoustic models of different languages (see Patent Document 2, for example), and so on have been proposed.

### CITATION LIST

### Patent Document

Patent Document 1: Japanese Patent Application Laid-Open No. 2015-18491

Patent Document 2: Japanese Patent Application Laid-Open No. 2015-161927

### SUMMARY OF THE INVENTION

### Problems to be Solved by the Invention

By the way, common acoustic models are assumed to operate on large-scale computers and the like, and the size of acoustic models is not particularly taken into account to achieve high recognition performance. As the size or scale of an acoustic model increases, the amount of computation at the time of recognition processing using the acoustic model increases correspondingly, resulting in a decrease in response speed.

However, speech recognition systems are also expected to operate at high speed on small devices and the like because of their usefulness as interfaces. It is difficult to use acoustic models built with large-scale computers in mind in such situations.

Specifically, for example, in embedded speech recognition that operates, for example, on a mobile terminal without communication with a network, it is difficult to operate a large-scale speech recognition system due to hardware limitations. An approach of reducing the size of an acoustic model or the like is required.

However, in a case where the size of an acoustic model is simply reduced, the recognition accuracy of speech recognition is greatly reduced. Thus, it is difficult to achieve both sufficient recognition accuracy and response speed. Therefore, it is necessary to sacrifice either recognition accuracy or response speed, which becomes a factor in increasing a burden on a user when using a speech recognition system as an interface.

The present technology has been made in view of such circumstances, and is intended to allow speech recognition with sufficient recognition accuracy and response speed.

### Solutions to Problems

A learning apparatus according to an aspect of the present technology includes a model learning unit that learns a model for recognition processing, on the basis of output of a decoder for the recognition processing constituting a conditional variational autoencoder when features extracted from learning data are input to the decoder, and the features.

A learning method or a program according to an aspect of the present technology includes a step of learning a model for recognition processing, on the basis of output of a decoder for the recognition processing constituting a conditional variational autoencoder when features extracted from learning data are input to the decoder, and the features.

According to an aspect of the present technology, a model for recognition processing is learned on the basis of output of a decoder for the recognition processing constituting a conditional variational autoencoder when features extracted from learning data are input to the decoder, and the features.

### Effects of the Invention

According to an aspect of the present technology, speech recognition can be performed with sufficient recognition accuracy and response speed.

Note that the effects described here are not necessarily limiting, and any effect described in the present disclosure may be included.

### BRIEF DESCRIPTION OF DRAWINGS

FIG. 1 is a diagram illustrating a configuration example of a learning apparatus.

FIG. 2 is a diagram illustrating a configuration example of a conditional variational autoencoder learning unit.

FIG. 3 is a diagram illustrating a configuration example of a neural network acoustic model learning unit.

FIG. 4 is a flowchart illustrating a learning process.

FIG. 5 is a flowchart illustrating a conditional variational autoencoder learning process.

FIG. 6 is a flowchart illustrating a neural network acoustic model learning process.

FIG. 7 is a diagram illustrating a configuration example of a computer.

### MODE FOR CARRYING OUT THE INVENTION

Hereinafter, an embodiment to which the present technology is applied will be described with reference to the drawings.

### First Embodiment

### Configuration Example of Learning Apparatus

The present technology allows sufficient recognition accuracy and response speed to be obtained even in a case where the model size of an acoustic model is limited.

Here, the size of an acoustic model, that is, the scale of an acoustic model refers to the complexity of an acoustic model. For example, in a case where an acoustic model is formed by a neural network, as the number of layers of the neural network increases, the acoustic model increases in complexity, and the scale (size) of the acoustic model increases.

As described above, as the scale of an acoustic model increases, the amount of computation increases, resulting in a decrease in response speed, but recognition accuracy in recognition processing (speech recognition) using the acoustic model increases.

In the present technology, a large-scale conditional variational autoencoder is learned in advance, and the conditional variational autoencoder is used to learn a small-sized neural network acoustic model. Thus, the small-sized neural network acoustic model is learned to imitate the conditional variational autoencoder, so that an acoustic model capable of achieving sufficient recognition performance with sufficient response speed can be obtained.

For example, in a case where an acoustic model larger in scale than a small-scale (small-sized) acoustic model to be obtained finally is used in the learning of the acoustic model, using a larger number of acoustic models in the learning of a small-scale acoustic model allows an acoustic model with higher recognition accuracy to be obtained.

In the present technology, for example, a single conditional variational autoencoder is used in the learning of a small-sized neural network acoustic model. Note that the neural network acoustic model is an acoustic model of a neural network structure, that is, an acoustic model formed by a neural network.

The conditional variational autoencoder includes an encoder and a decoder, and has a characteristic that changing a latent variable input changes the output of the conditional variational autoencoder. Therefore, even in a case where a single conditional variational autoencoder is used in the learning of a neural network acoustic model, learning equivalent to learning using a plurality of large-scale acoustic models can be performed, allowing a neural network acoustic model with small size but sufficient recognition accuracy to be easily obtained.

Note that the following describes, as an example, a case where a conditional variational autoencoder, more specifically, a decoder constituting the conditional variational autoencoder is used as a large-scale acoustic model, and a neural network acoustic model smaller in scale than the decoder is learned.

However, an acoustic model obtained by learning is not limited to a neural network acoustic model, and may be any other acoustic model. Moreover, a model obtained by learning is not limited to an acoustic model, and may be a model used in recognition processing on any recognition target such as image recognition.

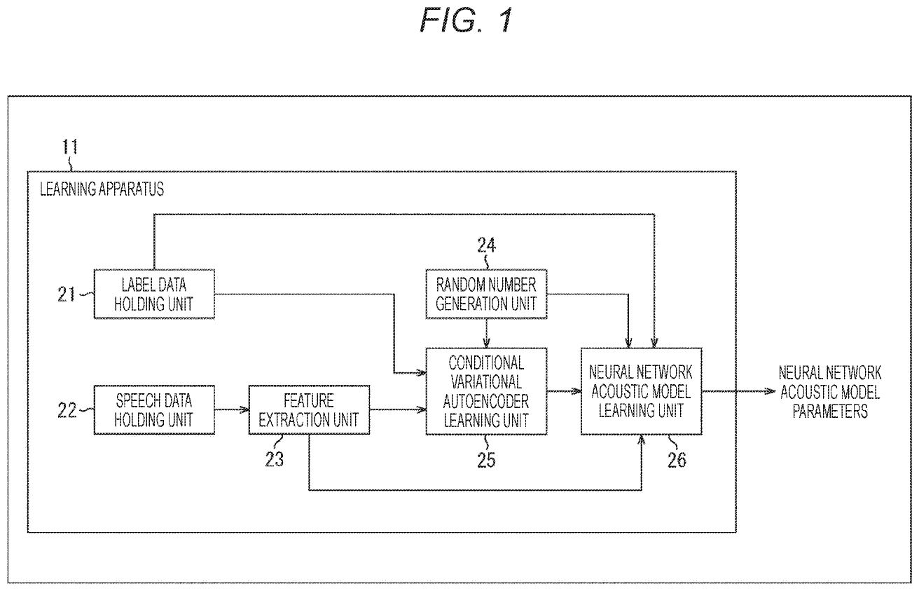

Then, a more specific embodiment to which the present technology is applied will be described below. FIG. 1 is a diagram illustrating a configuration example of a learning apparatus to which the present technology is applied.

A learning apparatus 11 illustrated in FIG. 1 includes a label data holding unit 21, a speech data holding unit 22, a feature extraction unit 23, a random number generation unit 24, a conditional variational autoencoder learning unit 25, and a neural network acoustic model learning unit 26.

The learning apparatus 11 learns a neural network acoustic model that performs recognition processing (speech recognition) on input speech data and outputs the results of the recognition processing. That is, parameters of the neural network acoustic model are learned.

Here, the recognition processing is processing to recognize whether a sound based on input speech data is a predetermined recognition target sound, such as which phoneme state the phoneme state of the sound based on the speech data is, in other words, processing to predict which recognition target sound it is. When such recognition processing is performed, the probability of being the recognition target sound is output as a result of the recognition processing, that is, a result of the recognition target prediction.

The label data holding unit 21 holds, as label data, data of a label indicating which recognition target sound learning speech data stored in the speech data holding unit 22 is, such as the phoneme state of the learning speech data. In other words, a label indicated by the label data is information indicating a correct answer when the recognition processing is performed on the speech data corresponding to the label data, that is, information indicating a correct recognition target.

Such label data is obtained, for example, by performing alignment processing on learning speech data prepared in advance on the basis of text information.

The label data holding unit 21 provides the label data it holds to the conditional variational autoencoder learning unit 25 and the neural network acoustic model learning unit 26.

The speech data holding unit 22 holds a plurality of pieces of learning speech data prepared in advance, and provides the pieces of speech data to the feature extraction unit 23.

Note that the label data holding unit 21 and the speech data holding unit 22 store the label data and the speech data in a state of being readable at high speed.

Furthermore, speech data and label data used in the conditional variational autoencoder learning unit 25 may be the same as or different from speech data and label data used in the neural network acoustic model learning unit 26.

The feature extraction unit 23 performs, for example, a Fourier transform and then performs filtering processing using a Mel filter bank or the like on the speech data provided from the speech data holding unit 22, thereby converting the speech data into acoustic features. That is, acoustic features are extracted from the speech data.

The feature extraction unit 23 provides the acoustic features extracted from the speech data to the conditional variational autoencoder learning unit 25 and the neural network acoustic model learning unit 26.

Note that in order to capture time-series information of the speech data, differential features obtained by calculating differences between acoustic features in temporally different frames of the speech data may be connected into final acoustic features. Furthermore, acoustic features in temporally continuous frames of the speech data may be connected into a final acoustic feature.

The random number generation unit 24 generates a random number required in the learning of a conditional variational autoencoder in the conditional variational autoencoder learning unit 25, and learning of a neural network acoustic model in the neural network acoustic model learning unit 26.

For example, the random number generation unit 24 generates a multidimensional random number v according to an arbitrary probability density function p(v) such as a multidimensional Gaussian distribution, and provides it to the conditional variational autoencoder learning unit 25 and the neural network acoustic model learning unit 26.

Here, for example, the multidimensional random number v is generated according to a multidimensional Gaussian distribution with the mean being the 0 vector, having a covariance matrix in which diagonal elements are 1 and the others are 0 due to the limitations of an assumed model of the conditional variational autoencoder.

Specifically, the random number generation unit 24 generates the multidimensional random number v according to a probability density given by calculating, for example, the following equation (1).

p(v)=N(v:0, I) (1)

Note that in equation (1), N(v, 0, I) represents a multidimensional Gaussian distribution. In particular, 0 in N(v, 0, I) represents the mean, and I represents the variance.

The conditional variational autoencoder learning unit 25 learns the conditional variational autoencoder on the basis of the label data from the label data holding unit 21, the acoustic features from the feature extraction unit 23, and the multidimensional random number v from the random number generation unit 24.

The conditional variational autoencoder learning unit 25 provides, to the neural network acoustic model learning unit 26, the conditional variational autoencoder obtained by learning, more specifically, parameters of the conditional variational autoencoder (hereinafter, referred to as conditional variational autoencoder parameters).

The neural network acoustic model learning unit 26 learns the neural network acoustic model on the basis of the label data from the label data holding unit 21, the acoustic features from the feature extraction unit 23, the multidimensional random number v from the random number generation unit 24, and the conditional variational autoencoder parameters from the conditional variational autoencoder learning unit 25.

Here, the neural network acoustic model is an acoustic model smaller in scale (size) than the conditional variational autoencoder. More specifically, the neural network acoustic model is an acoustic model smaller in scale than the decoder constituting the conditional variational autoencoder. The scale referred to here is the complexity of the acoustic model.

The neural network acoustic model learning unit 26 outputs, to a subsequent stage, the neural network acoustic model obtained by learning, more specifically, parameters of the neural network acoustic model (hereinafter, also referred to as neural network acoustic model parameters). The neural network acoustic model parameters are a coefficient matrix used in data conversion performed on input acoustic features when a label is predicted, for example.

### Configuration Example of Conditional Variational Autoencoder Learning Unit

Next, more detailed configuration examples of the conditional variational autoencoder learning unit 25 and the neural network acoustic model learning unit 26 illustrated in FIG. 1 will be described.

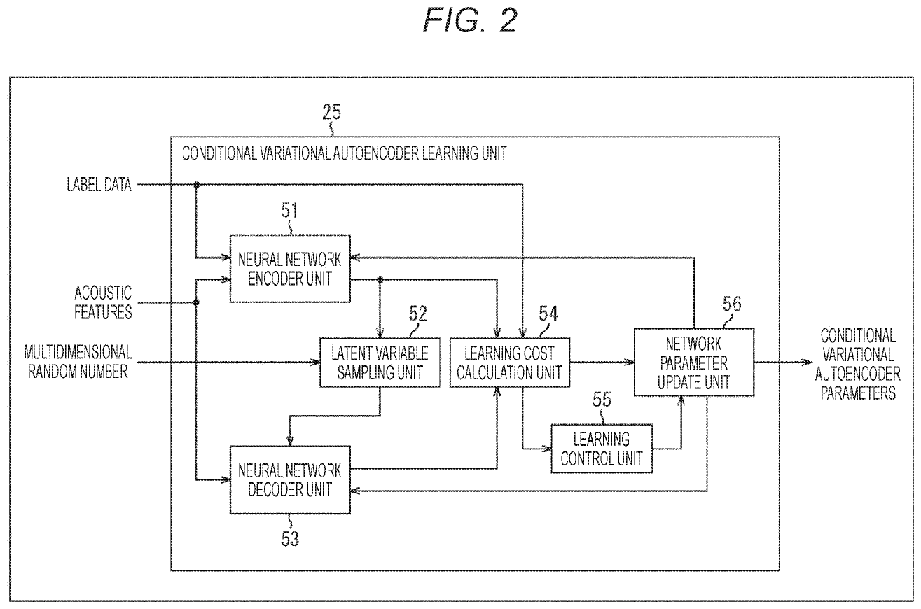

First, the configuration of the conditional variational autoencoder learning unit 25 will be described. For example, the conditional variational autoencoder learning unit 25 is configured as illustrated in FIG. 2.

The conditional variational autoencoder learning unit 25 illustrated in FIG. 2 includes a neural network encoder unit 51, a latent variable sampling unit 52, a neural network decoder unit 53, a learning cost calculation unit 54, a learning control unit 55, and a network parameter update unit 56.

The conditional variational autoencoder learned by the conditional variational autoencoder learning unit 25 is, for example, a model including an encoder and a decoder formed by a neural network. Of the encoder and the decoder, the decoder corresponds to the neural network acoustic model, and label prediction can be performed by the decoder.

The neural network encoder unit 51 functions as the encoder constituting the conditional variational autoencoder. The neural network encoder unit 51 calculates a latent variable distribution on the basis of the parameters of the encoder constituting the conditional variational autoencoder provided from the network parameter update unit 56 (hereinafter, also referred to as encoder parameters), the label data provided from the label data holding unit 21, and the acoustic features provided from the feature extraction unit 23.

Specifically, the neural network encoder unit 51 calculates a mean μ and a standard deviation vector σ as the latent variable distribution from the acoustic features corresponding to the label data, and provides them to the latent variable sampling unit 52 and the learning cost calculation unit 54. The encoder parameters are parameters of the neural network used when data conversion is performed to calculate the mean p and the standard deviation vector σ.

The latent variable sampling unit 52 samples a latent variable z on the basis of the multidimensional random number v provided from the random number generation unit 24, and the mean μ and the standard deviation vector σ provided from the neural network encoder unit 51.

That is, for example, the latent variable sampling unit 52 generates the latent variable z by calculating the following equation (2), and provides the obtained latent variable z to the neural network decoder unit 53.

z=vₜ×σₜ+μₜ (2)

Note that in equation (2) , vₜ, σₜ, and μₜ represent the multidimensional random number v generated according to the multidimensional Gaussian distribution p(v), the standard deviation vector σ, and the mean μ, respectively, and t in vₜ, σₜ, and μₜ represents a time index. Further, in equation (2) , “x” represents the element product between the vectors. In the calculation of equation (2), the latent variable z corresponding to a new multidimensional random number is generated by changing the mean and the variance of the multidimensional random number v.

The neural network decoder unit 53 functions as the decoder constituting the conditional variational autoencoder.

The neural network decoder unit 53 predicts a label corresponding to the acoustic features, on the basis of the parameters of the decoder constituting the conditional variational autoencoder provided from the network parameter update unit 56 (hereinafter, also referred to as decoder parameters), the acoustic features provided from the feature extraction unit 23, and the latent variable z provided from the latent variable sampling unit 52, and provides the prediction result to the learning cost calculation unit 54.

That is, the neural network decoder unit 53 performs an operation on the basis of the decoder parameters, the acoustic features, and the latent variable z, and obtains, as a label prediction result, the probability that the speech based on the speech data corresponding to the acoustic features is the recognition target speech indicated by the label.

Note that the decoder parameters are parameters of the neural network used in an operation such as data conversion for predicting a label.

The learning cost calculation unit 54 calculates a learning cost of the conditional variational autoencoder, on the basis of the label data from the label data holding unit 21, the latent variable distribution from the neural network encoder unit 51, and the prediction result from the neural network decoder unit 53.

For example, the learning cost calculation unit 54 calculates an error L as the learning cost by calculating the following equation (3), on the basis of the label data, the latent variable distribution, and the label prediction result. In equation (3), the error L based on cross entropy is determined.

L=−Σₜ₌₁^{T}Σₖ₌₁^{K}δ(kₜ, lₜ)log(p_{decoder}(kₜ))+KL(p_{encoder}(v)||(v)) (3)

Note that in equation (3), kₜ is an index representing a label indicated by the label data, and lₜ is an index representing a label that is a correct answer in prediction (recognition) among the labels indicated by the label data. Further, in equation (3), δ(kₜ, lₜ) represents a delta function in which the value becomes one only in a case where kₜ=lₜ.

Further, in equation (3) p_{decoder} (kₜ) represents a label prediction result output from the neural network decoder unit 53, and p_{encoder} (v) represents a latent variable distribution including the mean p and the standard deviation vector 6 output from the neural network encoder unit 51.

Furthermore, in equation (3), KL(p_{encoder}(v)||p(v)) is the KL-divergence representing the distance between the latent variable distributions, that is, the distance between the distribution pₑncoder(v) of the latent variable and the distribution p(v) of the multidimensional random number that is the output of the random number generation unit 24.

For the error L determined by equation (3), as the prediction accuracy of the label prediction performed by the conditional variational autoencoder, that is, the percentage of correct answers of the prediction increases, the value of the error L decreases. It can be said that the error L like this represents the degree of progress in the learning of the conditional variational autoencoder.

In the learning of the conditional variational autoencoder, the conditional variational autoencoder parameters, that is, the encoder parameters and the decoder parameters are updated so that the error L decreases.

The learning cost calculation unit 54 provides the determined error L to the learning control unit 55 and the network parameter update unit 56.

The learning control unit 55 controls the parameters at the time of learning of the conditional variational autoencoder, on the basis of the error L provided from the learning cost calculation unit 54.

For example, here, the conditional variational autoencoder is learned using an error backpropagation method. In that case, the learning control unit 55 determines parameters of the error backpropagation method such as learning coefficients and batch size, on the basis of the error L, and provides the determined parameters to the network parameter update unit 56.

The network parameter update unit 56 learns the conditional variational autoencoder using the error backpropagation method, on the basis of the error L provided from the learning cost calculation unit 54 and the parameters of the error backpropagation method provided from the learning control unit 55.

That is, the network parameter update unit 56 updates the encoder parameters and the decoder parameters as the conditional variational autoencoder parameters using the error backpropagation method so that the error L decreases.

The network parameter update unit 56 provides the updated encoder parameters to the neural network encoder unit 51, and provides the updated decoder parameters to the neural network decoder unit 53.

Furthermore, in a case where the network parameter update unit 56 determines that the cycle of a learning process performed by the neural network encoder unit 51 to the network parameter update unit 56 has been performed a certain number of times, and the learning has converged sufficiently, it finishes the learning. Then, the network parameter update unit 56 provides the conditional variational autoencoder parameters obtained by the learning to the neural network acoustic model learning unit 26.

### Configuration Example of Neural Network Acoustic Model Learning Unit

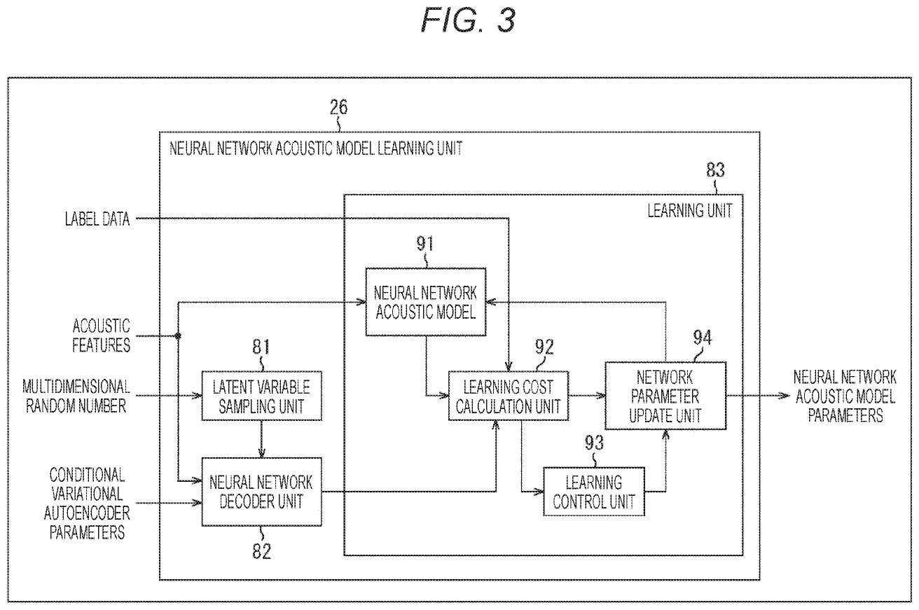

Next, a configuration example of the neural network acoustic model learning unit 26 will be described. The neural network acoustic model learning unit 26 is configured as illustrated in FIG. 3, for example.

The neural network acoustic model learning unit 26 illustrated in FIG. 3 includes a latent variable sampling unit 81, a neural network decoder unit 82, and a learning unit 83.

The neural network acoustic model learning unit 26 learns the neural network acoustic model using the conditional variational autoencoder parameters provided from the network parameter update unit 56, and the multidimensional random number v.

The latent variable sampling unit 81 samples a latent variable on the basis of the multidimensional random number v provided from the random number generation unit 24, and provides the obtained latent variable to the neural network decoder unit 82. In other words, the latent variable sampling unit 81 functions as a generation unit that generates a latent variable on the basis of the multidimensional random number v.

For example, here, both the multidimensional random number and the latent variable are on the assumption of a multidimensional Gaussian distribution with the mean being the 0 vector, having a covariance matrix in which diagonal elements are 1 and the others are 0, and thus the multidimensional random number v is output directly as the latent variable. This is because the KL-divergence between the latent variable distributions in the above-described equation (3) has converged sufficiently due to the learning of the conditional variational autoencoder parameters.

Note that the latent variable sampling unit 81 may generate a latent variable with the mean and the standard deviation vector shifted, like the latent variable sampling unit 52.

The neural network decoder unit 82 functions as the decoder of the conditional variational autoencoder that performs label prediction using the conditional variational autoencoder parameters, more specifically, the decoder parameters provided from the network parameter update unit 56.

The neural network decoder unit 82 predicts a label corresponding to the acoustic features on the basis of the decoder parameters provided from the network parameter update unit 56, the acoustic features provided from the feature extraction unit 23, and the latent variable provided from the latent variable sampling unit 81, and provides the prediction result to the learning unit 83.

That is, the neural network decoder unit 82 corresponds to the neural network decoder unit 53, performs an operation such as data conversion on the basis of the decoder parameters, the acoustic features, and the latent variable, and obtains, as a label prediction result, the probability that the speech based on the speech data corresponding to the acoustic features is the recognition target speech indicated by the label.

For the label prediction, that is, the recognition processing on the speech data, the encoder constituting the conditional variational autoencoder is unnecessary. However, it is impossible to learn only the decoder of the conditional variational autoencoder. Therefore, the conditional variational autoencoder learning unit 25 learns the conditional variational autoencoder including the encoder and the decoder.

The learning unit 83 learns the neural network acoustic model on the basis of the label data from the label data holding unit 21, the acoustic features from the feature extraction unit 23, and the label prediction result provided from the neural network decoder unit 82.

In other words, the learning unit 83 learns the neural network acoustic model parameters, on the basis of the output of the decoder constituting the conditional variational autoencoder when the acoustic features and the latent variable are input to the decoder, the acoustic features, and the label data.

By thus using the large-scale decoder in the learning of the small-scale neural network acoustic model for performing recognition processing (speech recognition) similar to that of the decoder, in which label prediction is performed, the neural network acoustic model is learned to imitate the decoder. As a result, the neural network acoustic model with high recognition performance despite its small scale can be obtained.

The learning unit 83 includes a neural network acoustic model 91, a learning cost calculation unit 92, a learning control unit 93, and a network parameter update unit 94.

The neural network acoustic model 91 functions as a neural network acoustic model learned by performing an operation based on neural network acoustic model parameters provided from the network parameter update unit 94.

The neural network acoustic model 91 predicts a label corresponding to the acoustic features on the basis of the neural network acoustic model parameters provided from the network parameter update unit 94 and the acoustic features from the feature extraction unit 23, and provides the prediction result to the learning cost calculation unit 92.

That is, the neural network acoustic model 91 performs an operation such as data conversion on the basis of the neural network acoustic model parameters and the acoustic features, and obtains, as a label prediction result, the probability that the speech based on the speech data corresponding to the acoustic features is the recognition target speech indicated by the label. The neural network acoustic model 91 does not require a latent variable, and performs label prediction only with the acoustic features as input.

The learning cost calculation unit 92 calculates the learning cost of the neural network acoustic model on the basis of the label data from the label data holding unit 21, the prediction result from the neural network acoustic model 91, and the prediction result from the neural network decoder unit 82.

For example, the learning cost calculation unit 92 calculates the following equation (4) on the basis of the label data, the result of label prediction by the neural network acoustic model, and the result of label prediction by the decoder, thereby calculating an error L as the learning cost. In equation (4), the error L is determined by extending cross entropy.

L=−(1−α)Σₜ₌₁^{T}Σₖ₌₁^{K}δ(kₜ, lₜ)log(p(kₜ))−αΣₜ₌₁^{T}Σₖ₌₁^{K}p_{decoder}(kₜ)log(p(kₜ)) (4)

Note that in equation (4), kₜ is an index representing a label indicated by the label data, and lₜ is an index representing a label that is a correct answer in prediction (recognition) among the labels indicated by the label data. Furthermore, in equation (4), δ(kₜ, lₜ) represents a delta function in which the value becomes one only if kₜ=lₜ.

Moreover, in equation (4), p(kₜ) represents a label prediction result output from the neural network acoustic model 91, and P_{decoder} (kₜ) represents a label prediction result output from the neural network decoder unit 82.

In equation (4), the first term on the right side represents cross entropy for the label data, and the second term on the right side represents cross entropy for the neural network decoder unit 82 using the decoder parameters of the conditional variational autoencoder.

Furthermore, α in equation (4) is an interpolation parameter of the cross entropy. The interpolation parameter a can be freely selected in advance in the range of 0 a 1. For example, letting α=1.0, the learning of the neural network acoustic model is performed.

The error L determined by equation (4) includes a term on an error between the result of label prediction by the neural network acoustic model and the correct answer, and a term on an error between the result of label prediction by the neural network acoustic model and the result of label prediction by the decoder. Thus, the value of the error L decreases as the accuracy of the label prediction by the neural network acoustic model, that is, the percentage of correct answers increases, and as the result of prediction by the neural network acoustic model approaches the result of prediction by the decoder.

It can be said that the error L like this indicates the degree of progress in the learning of the neural network acoustic model. In the learning of the neural network acoustic model, the neural network acoustic model parameters are updated so that the error L decreases.

The learning cost calculation unit 92 provides the determined error L to the learning control unit 93 and the network parameter update unit 94.

The learning control unit 93 controls parameters at the time of learning the neural network acoustic model, on the basis of the error L provided from the learning cost calculation unit 92.

For example, here, the neural network acoustic model is learned using an error backpropagation method. In that case, the learning control unit 93 determines parameters of the error backpropagation method such as learning coefficients and batch size, on the basis of the error L, and provides the determined parameters to the network parameter update unit 94.

The network parameter update unit 94 learns the neural network acoustic model using the error backpropagation method, on the basis of the error L provided from the learning cost calculation unit 92 and the parameters of the error backpropagation method provided from the learning control unit 93.

That is, the network parameter update unit 94 updates the neural network acoustic model parameters using the error backpropagation method so that the error L decreases.

The network parameter update unit 94 provides the updated neural network acoustic model parameters to the neural network acoustic model 91.

Furthermore, in a case where the network parameter update unit 94 determines that the cycle of a learning process performed by the latent variable sampling unit 81 to the network parameter update unit 94 has been performed a certain number of times, and the learning has converged sufficiently, it finishes the learning. Then, the network parameter update unit 94 outputs the neural network acoustic model parameters obtained by the learning to a subsequent stage.

The learning apparatus 11 as described above can build acoustic model learning that imitates the recognition performance of a large-scale model with high performance while keeping the model size of a neural network acoustic model small. This allows the provision of a neural network acoustic model with sufficient speech recognition performance while preventing an increase in response time, even in a computing environment with limited computational resources such as embedded speech recognition, or the like, and can improve usability.

### Explanation of Learning Process

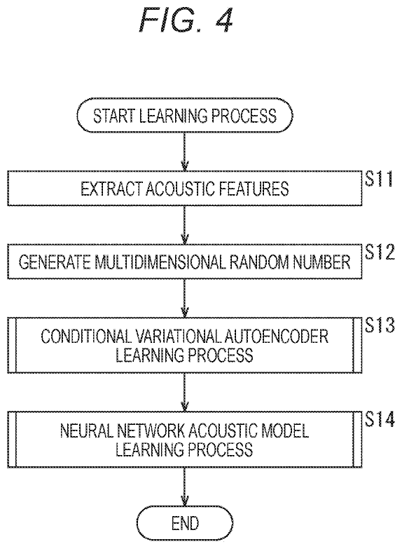

Next, the operation of the learning apparatus 11 will be described. That is, a learning process performed by the learning apparatus 11 will be described below with reference to a flowchart in FIG. 4.

In step S11, the feature extraction unit 23 extracts acoustic features from speech data provided from the speech data holding unit 22, and provides the obtained acoustic features to the conditional variational autoencoder learning unit 25 and the neural network acoustic model learning unit 26.

In step S12, the random number generation unit 24 generates the multidimensional random number v, and provides it to the conditional variational autoencoder learning unit 25 and the neural network acoustic model learning unit 26. For example, in step S12, the calculation of the above-described equation (1) is performed to generate the multidimensional random number v.

In step S13, the conditional variational autoencoder learning unit 25 performs a conditional variational autoencoder learning process, and provides conditional variational autoencoder parameters obtained to the neural network acoustic model learning unit 26. Note that the details of the conditional variational autoencoder learning process will be described later.

In step S14, the neural network acoustic model learning unit 26 performs a neural network acoustic model learning process on the basis of the conditional variational autoencoder provided from the conditional variational autoencoder learning unit 25, and outputs the resulting neural network acoustic model parameters to the subsequent stage.

Then, when the neural network acoustic model parameters are output, the learning process is finished. Note that the details of the neural network acoustic model learning process will be described later.

As described above, the learning apparatus 11 learns a conditional variational autoencoder, and learns a neural network acoustic model using the conditional variational autoencoder obtained. With this, a neural network acoustic model with small scale but sufficiently high recognition accuracy (recognition performance) can be easily obtained, using a large-scale conditional variational autoencoder. That is, by using the neural network acoustic model obtained, speech recognition can be performed with sufficient recognition accuracy and response speed.

### Explanation of Conditional Variational Autoencoder Learning Process

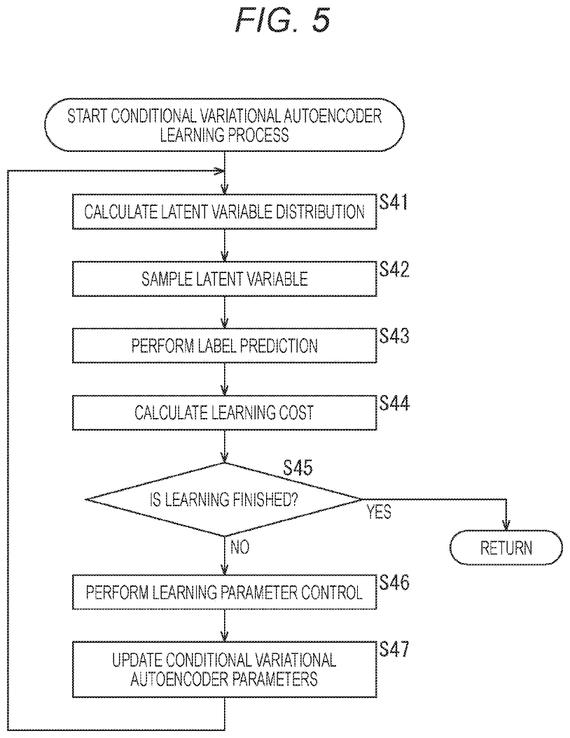

Here, the conditional variational autoencoder learning process corresponding to the process of step S13 in the learning process of FIG. 4 will be described. That is, with reference to a flowchart in FIG. 5, the conditional variational autoencoder learning process performed by the conditional variational autoencoder learning unit 25 will be described below.

In step S41, the neural network encoder unit 51 calculates a latent variable distribution on the basis of the encoder parameters provided from the network parameter update unit 56, the label data provided from the label data holding unit 21, and the acoustic features provided from the feature extraction unit 23.

The neural network encoder unit 51 provides the mean p and the standard deviation vector σ as the calculated latent variable distribution to the latent variable sampling unit 52 and the learning cost calculation unit 54.

In step S42, the latent variable sampling unit 52 samples the latent variable z on the basis of the multidimensional random number v provided from the random number generation unit 24, and the mean p and the standard deviation vector σ provided from the neural network encoder unit 51. That is, for example, the calculation of the above-described equation (2) is performed, and the latent variable z is generated.

The latent variable sampling unit 52 provides the latent variable z obtained by the sampling to the neural network decoder unit 53.

In step S43, the neural network decoder unit 53 predicts a label corresponding to the acoustic features, on the basis of the decoder parameters provided from the network parameter update unit 56, the acoustic features provided from the feature extraction unit 23, and the latent variable z provided from the latent variable sampling unit 52. Then, the neural network decoder unit 53 provides the label prediction result to the learning cost calculation unit 54.

In step S44, the learning cost calculation unit 54 calculates the learning cost on the basis of the label data from the label data holding unit 21, the latent variable distribution from the neural network encoder unit 51, and the prediction result from the neural network decoder unit 53.

For example, in step S44, the error L expressed in the above-described equation (3) is calculated as the learning cost. The learning cost calculation unit 54 provides the calculated learning cost, that is, the error L to the learning control unit 55 and the network parameter update unit 56.

In step S45, the network parameter update unit 56 determines whether or not to finish the learning of the conditional variational autoencoder.

For example, the network parameter update unit 56 determines that the learning will be finished in a case where processing to update the conditional variational autoencoder parameters has been performed a sufficient number of times, and the difference between the error L obtained in processing of step S44 performed last time and the error L obtained in the processing of step S44 performed immediately before that time has become lower than or equal to a predetermined threshold.

In a case where it is determined in step S45 that the learning will not yet be finished, the process proceeds to step S46 thereafter, to perform the processing to update the conditional variational autoencoder parameters.

In step S46, the learning control unit 55 performs parameter control on the learning of the conditional variational autoencoder, on the basis of the error L provided from the learning cost calculation unit 54, and provides the parameters of the error backpropagation method determined by the parameter control to the network parameter update unit 56.

In step S47, the network parameter update unit 56 updates the conditional variational autoencoder parameters using the error backpropagation method, on the basis of the error L provided from the learning cost calculation unit 54 and the parameters of the error backpropagation method provided from the learning control unit 55.

The network parameter update unit 56 provides the updated encoder parameters to the neural network encoder unit 51, and provides the updated decoder parameters to the neural network decoder unit 53. Then, after that, the process returns to step S41, and the above-described process is repeatedly performed, using the updated new encoder parameters and decoder parameters.

Furthermore, in a case where it is determined in step S45 that the learning will be finished, the network parameter update unit 56 provides the conditional variational autoencoder parameters obtained by the learning to the neural network acoustic model learning unit 26, and the conditional variational autoencoder learning process is finished. When the conditional variational autoencoder learning process is finished, the process of step S13 in FIG. 4 is finished. Thus, after that, the process of step S14 is performed.

The conditional variational autoencoder learning unit 25 learns the conditional variational autoencoder as described above. By thus learning the conditional variational autoencoder in advance, the conditional variational autoencoder obtained by the learning can be used in the learning of the neural network acoustic model.

### Explanation of Neural Network Acoustic Model Learning Process

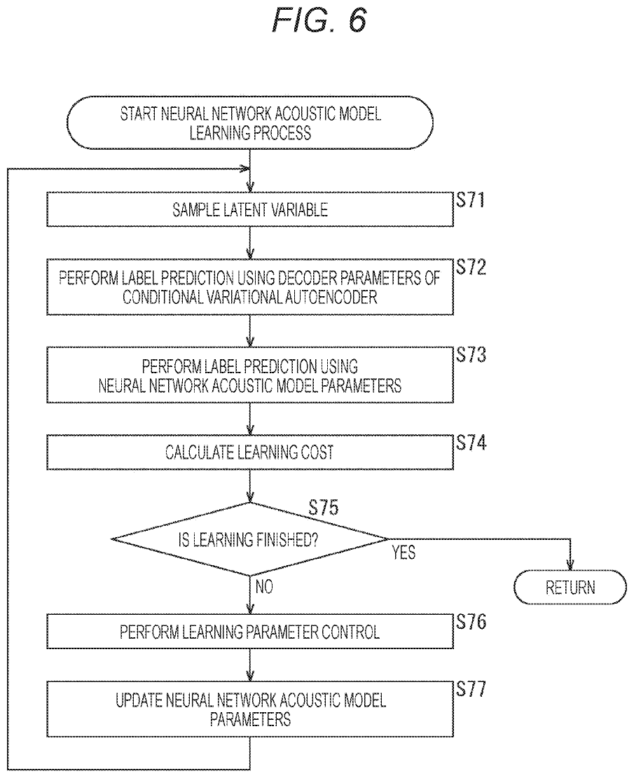

Moreover, the neural network acoustic model learning process corresponding to the process of step S14 in the learning process of FIG. 4 will be described. That is, with reference to a flowchart in FIG. 6, the neural network acoustic model learning process performed by the neural network acoustic model learning unit 26 will be described below.

In step S71, the latent variable sampling unit 81 samples a latent variable on the basis of the multidimensional random number v provided from the random number generation unit 24, and provides the latent variable obtained to the neural network decoder unit 82. Here, for example, the multidimensional random number v is directly used as the latent variable.

In step S72, the neural network decoder unit 82 performs label prediction using the decoder parameters of the conditional variational autoencoder provided from the network parameter update unit 56, and provides the prediction result to the learning cost calculation unit 92.

That is, the neural network decoder unit 82 predicts a label corresponding to the acoustic features, on the basis of the decoder parameters provided from the network parameter update unit 56, the acoustic features provided from the feature extraction unit 23, and the latent variable provided from the latent variable sampling unit 81.

In step S73, the neural network acoustic model 91 performs label prediction using the neural network acoustic model parameters provided from the network parameter update unit 94, and provides the prediction result to the learning cost calculation unit 92.

That is, the neural network acoustic model 91 predicts a label corresponding to the acoustic features on the basis of the neural network acoustic model parameters provided from the network parameter update unit 94, and the acoustic features from the feature extraction unit 23.

In step S74, the learning cost calculation unit 92 calculates the learning cost of the neural network acoustic model on the basis of the label data from the label data holding unit 21, the prediction result from the neural network acoustic model 91, and the prediction result from the neural network decoder unit 82.

For example, in step S74, the error L expressed in the above-described equation (4) is calculated as the learning cost. The learning cost calculation unit 92 provides the calculated learning cost, that is, the error L to the learning control unit 93 and the network parameter update unit 94.

In step S75, the network parameter update unit 94 determines whether or not to finish the learning of the neural network acoustic model.

For example, the network parameter update unit 94 determines that the learning will be finished in a case where processing to update the neural network acoustic model parameters has been performed a sufficient number of times, and the difference between the error L obtained in processing of step S74 performed last time and the error L obtained in the processing of step S74 performed immediately before that time has become lower than or equal to a predetermined threshold.

In a case where it is determined in step S75 that the learning will not yet be finished, the process proceeds to step S76 thereafter, to perform the processing to update the neural network acoustic model parameters.

In step S76, the learning control unit 93 performs parameter control on the learning of the neural network acoustic model, on the basis of the error L provided from the learning cost calculation unit 92, and provides the parameters of the error backpropagation method determined by the parameter control to the network parameter update unit 94.

In step S77, the network parameter update unit 94 updates the neural network acoustic model parameters using the error backpropagation method, on the basis of the error L provided from the learning cost calculation unit 92 and the parameters of the error backpropagation method provided from the learning control unit 93.

The network parameter update unit 94 provides the updated neural network acoustic model parameters to the neural network acoustic model 91. Then, after that, the process returns to step S71, and the above-described process is repeatedly performed, using the updated new neural network acoustic model parameters.

Furthermore, in a case where it is determined in step S75 that the learning will be finished, the network parameter update unit 94 outputs the neural network acoustic model parameters obtained by the learning to the subsequent stage, and the neural network acoustic model learning process is finished. When the neural network acoustic model learning process is finished, the process of step S14 in FIG. 4 is finished, and thus the learning process in FIG. 4 is also finished.

As described above, the neural network acoustic model learning unit 26 learns the neural network acoustic model, using the conditional variational autoencoder obtained by learning in advance. Consequently, the neural network acoustic model capable of performing speech recognition with sufficient recognition accuracy and response speed can be obtained.

### Configuration Example of Computer

By the way, the above-described series of process steps can be performed by hardware, or can be performed by software. In a case where the series of process steps is performed by software, a program constituting the software is installed on a computer. Here, computers include computers incorporated in dedicated hardware, general-purpose personal computers, for example, which can execute various functions by installing various programs, and so on.

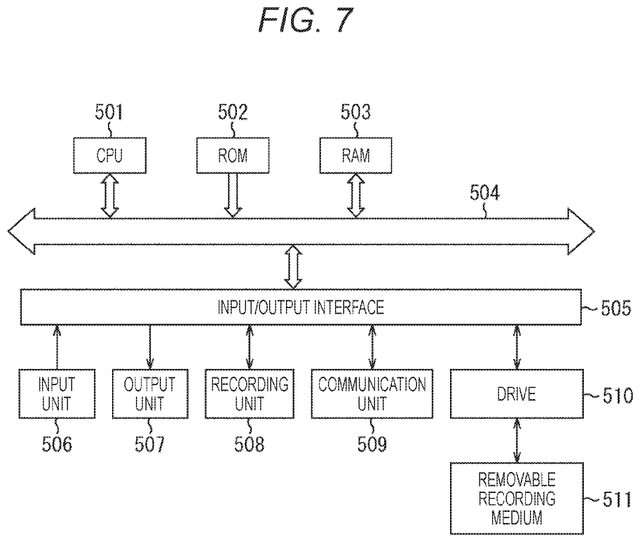

FIG. 7 is a block diagram illustrating a hardware configuration example of a computer that performs the above-described series of process steps using a program.

In the computer, a central processing unit (CPU) 501, a read-only memory (ROM) 502, and a random-access memory (RAM) 503 are mutually connected by a bus 504.

An input/output interface 505 is further connected to the bus 504. An input unit 506, an output unit 507, a recording unit 508, a communication unit 509, and a drive 510 are connected to the input/output interface 505.

The input unit 506 includes a keyboard, a mouse, a microphone, and an imaging device, for example. The output unit 507 includes a display and a speaker, for example. The recording unit 508 includes a hard disk and nonvolatile memory, for example. The communication unit 509 includes a network interface, for example. The drive 510 drives a removable recording medium 511 such as a magnetic disk, an optical disk, a magneto-optical disk, or a semiconductor memory.

In the computer configured as described above, the CPU 501 loads a program recorded on the recording unit 508, for example, into the RAM 503 via the input/output interface 505 and the bus 504, and executes it, thereby performing the above-described series of process steps.

The program executed by the computer (CPU 501) can be recorded on the removable recording medium 511 as a package medium or the like to be provided, for example. Furthermore, the program can be provided via a wired or wireless transmission medium such as a local area network, the Internet, or digital satellite broadcasting.

In the computer, the program can be installed in the recording unit 508 via the input/output interface 505 by putting the removable recording medium 511 into the drive 510. Furthermore, the program can be received by the communication unit 509 via a wired or wireless transmission medium and installed in the recording unit 508. In addition, the program can be installed in the ROM 502 or the recording unit 508 in advance.

Note that the program executed by the computer may be a program under which processing is performed in time series in the order described in the present description, or may be a program under which processing is performed in parallel or at a necessary timing such as when a call is made.

Furthermore, embodiments of the present technology are not limited to the above-described embodiment, and various modifications can be made without departing from the scope of the present technology.

For example, the present technology can have a configuration of cloud computing in which one function is shared by a plurality of apparatuses via a network and processed in cooperation.

Furthermore, each step described in the above-described flowcharts can be executed by a single apparatus, or can be shared and executed by a plurality of apparatuses.

Moreover, in a case where a plurality of process steps is included in a single step, the plurality of process steps included in the single step can be executed by a single apparatus, or can be shared and executed by a plurality of apparatuses.

Further, the present technology may have the following configurations.

(1)

A learning apparatus including

a model learning unit that learns a model for recognition processing, on the basis of output of a decoder for the recognition processing constituting a conditional variational autoencoder when features extracted from learning data are input to the decoder, and the features.

(2)

The learning apparatus according to (1), in which scale of the model is smaller than scale of the decoder.

(3)

The learning apparatus according to (2), in which the scale is complexity of the model.

(4)

The learning apparatus according to any one of (1) to (3), in which

the data is speech data, and the model is an acoustic model.

(5)

The learning apparatus according to (4), in which the acoustic model includes a neural network.

(6)

The learning apparatus according to any one of (1) to (5), in which

the model learning unit learns the model using an error backpropagation method.

(7)

The learning apparatus according to any one of (1) to (6), further including:

a generation unit that generates a latent variable on the basis of a random number; and

the decoder that outputs a result of the recognition processing based on the latent variable and the features.

(8)

The learning apparatus according to any one of (1) to (7), further including

a conditional variational autoencoder learning unit that learns the conditional variational autoencoder.

(9)

A learning method including

learning, by a learning apparatus, a model for recognition processing, on the basis of output of a decoder for the recognition processing constituting a conditional variational autoencoder when features extracted from learning data are input to the decoder, and the features.

(10)

A program causing a computer to execute processing including

a step of learning a model for recognition processing, on the basis of output of a decoder for the recognition processing constituting a conditional variational autoencoder when features extracted from learning data are input to the decoder, and the features.

### REFERENCE SIGNS LIST

11 Learning apparatus

23 Feature extraction unit

24 Random number generation unit

25 Conditional variational autoencoder learning unit

26 Neural network acoustic model learning unit

81 Latent variable sampling unit

82 Neural network decoder unit

83 Learning unit

1. A learning apparatus comprising
a model learning unit that learns a model for recognition processing, on a basis of output of a decoder for the recognition processing constituting a conditional variational autoencoder when features extracted from learning data are input to the decoder, and the features.

2. The learning apparatus according to claim 1, wherein
scale of the model is smaller than scale of the decoder.

3. The learning apparatus according to claim 2, wherein
the scale is complexity of the model.

4. The learning apparatus according to claim 1, wherein
the data is speech data, and the model is an acoustic model.

5. The learning apparatus according to claim 4, wherein
the acoustic model comprises a neural network.

6. The learning apparatus according to claim 1, wherein
the model learning unit learns the model using an error backpropagation method.

7. The learning apparatus according to claim 1, further comprising:
a generation unit that generates a latent variable on a basis of a random number; and
the decoder that outputs a result of the recognition processing based on the latent variable and the features.

8. The learning apparatus according to claim 1, further comprising
a conditional variational autoencoder learning unit that learns the conditional variational autoencoder.

9. A learning method comprising
learning, by a learning apparatus, a model for recognition processing, on a basis of output of a decoder for the recognition processing constituting a conditional variational autoencoder when features extracted from learning data are input to the decoder, and the features.

10. A program causing a computer to execute processing comprising
a step of learning a model for recognition processing, on a basis of output of a decoder for the recognition processing constituting a conditional variational autoencoder when features extracted from learning data are input to the decoder, and the features.
